(19) United States
(12) Patent Application Publication
(10) Pub. No.: US 2026/0190876 A1
(43) Pub. Date: Jul. 2, 2026

(54) METHOD FOR MANUFACTURING SEMICONDUCTOR DEVICE, AND SEMICONDUCTOR DEVICE

(71) Applicant: Resonac Corporation, Minato-ku, Tokyo (JP)

(72) Inventors: Hirokazu NOMA, Minato-ku, Tokyo (JP); Toshiaki SHIRASAKA, Minato-ku, Tokyo (JP)

(21) Appl. No.: 18/859,551

(22) PCT Filed: Jun. 7, 2023
(86) PCT No.: PCT/JP2023/021165

§ 371 Date: Oct. 24, 2024

(51) Int. Cl. H10P 10/00; H10P 74/20

(52) U.S. Cl. CPC H10P 10/12; H10P 74/20

(57) ABSTRACT

As an example of a method for manufacturing a semiconductor device, four semiconductor wafers 40, 50, 60, and 70 are prepared. In this manufacturing method, the semiconductor wafer 40 and the semiconductor wafer 50 are bonded to each other by hybrid bonding to fabricate a stacked wafer 100. Similarly, the semiconductor wafer 60 and the semiconductor wafer 70 are bonded to each other by hybrid bonding to fabricate another stacked wafer 110. Thereafter, the stacked wafer 100 and the other stacked wafer 110 are further bonded to each other by hybrid bonding to fabricate a stacked wafer 120. According to this method, the process can be shortened as compared with a case of sequentially stacking layers one by one, and an effect of shortening the process is remarkable particularly when the number of stacked layers is large.

### TECHNICAL FIELD

The present disclosure relates to a method for manufacturing a semiconductor device, and the semiconductor device.

### BACKGROUND ART

Non Patent Literatures 1 and 2 disclose a method of bonding semiconductor wafers to each other (wafer to wafer bonding) and a method of bonding divided semiconductor chips to a semiconductor wafer (chip to wafer bonding). The method of bonding the semiconductor wafers to each other is a method of stacking wafers on each other on which a large number of semiconductor dies are formed, and has higher manufacturing efficiency than a method of bonding semiconductor chips obtained by dividing one semiconductor wafer to the other semiconductor wafer. Non Patent Literature 3 discloses a method of sequentially stacking semiconductor wafers one by one as a method of bonding such semiconductor wafers. Note that Non Patent Literature 4 discloses that 176 semiconductor layers are stacked in a laminated memory by a wire bonding method.

### CITATION LIST

### Non Patent Literature

Non Patent Literature 1: Adel Elsherbini et al., “Enabling Hybrid Bonding on Intel Process”, 2021 IEEE International Electron Devices Meeting (IEDM), IEDM21-729 to 732
Non Patent Literature 2: Fumihiro Inoue et al., “Advanced Dicing Technologies for Combination of Wafer to Wafer and Collective Die to Wafer Direct Bonding”, 2019 IEEE 69th Electronic Components and Technology Conference (ECTC), pp. 437-445
Non Patent Literature 3: TaeSeong Kim et al., “Multi-Stack Wafer Bonding Demonstration utilizing Cu to Cu Hybrid Bonding and TSV enabling Diverse 3D Integration”, 2021 IEEE 71st Electronic Components and Technology Conference (ECTC), pp. 415-419
Non Patent Literature 4: “Micron B47R 3D CTF CuA NAND Die, World's First 176L′195T”, [online] Aug. 19, 2021, [retrieved on May 14, 2023], Internet <URL: https://semiengineering.com/micron-b47r-3d-ctf-cua-nand-die-worlds-first-1761-195t/>
Non Patent Literature 5: S. Yoneda et al., “A Novel Photosensitive Polyimide Adhesive Material for Hybrid Bonding Processing”, 2021 IEEE 71st Electronic Components and Technology Conference (ECTC), San Diego, CA, USA, 2021, pp. 680-686
Non Patent Literature 6: Yoshiyuki Nozawa, “Silicon Deep Digging Technology with Bosch Etcher”, Journal of the Vacuum Society of Japan, No. 7, Volume 53 pp. 446-453, 2010

### SUMMARY OF INVENTION

### Technical Problem

As described above, in the method of bonding semiconductor wafers to each other, the semiconductor wafers are sequentially stacked one by one, and thus, a period for manufacturing a stacked body of the semiconductor wafers becomes longer in proportion to the number of stacked layers. In particular, in a case where semiconductor wafers of a large number of layers (for example, ten layers or more) are stacked, a period for manufacturing the stacked body is significantly prolonged. Thus, there is a demand for development of a method capable of shortening a period for manufacturing a stacked body of semiconductor wafers.

An object of the present disclosure is to provide a method for manufacturing a semiconductor device capable of shortening a period for manufacturing a stacked body of semiconductor wafers.

### Solution to Problem

[1] The present disclosure relates to, as one aspect, a method for manufacturing a semiconductor device. The method for manufacturing a semiconductor device includes: preparing a first semiconductor wafer, the first semiconductor wafer including a first semiconductor substrate, a first electrode provided on a first surface of the first semiconductor substrate, a second electrode provided on a second surface of the first semiconductor substrate, and a wiring, the wiring including a first through electrode penetrating the first semiconductor substrate to connect the first electrode and the second electrode to each other; preparing a second semiconductor wafer, the second semiconductor wafer including a second semiconductor substrate, a third electrode provided on a first surface of the second semiconductor substrate, a fourth electrode provided on a second surface of the second semiconductor substrate, and a wiring, the wiring including a second through electrode penetrating the second semiconductor substrate to connect the third electrode and the fourth electrode to each other; preparing a third semiconductor wafer, the third semiconductor wafer including a third semiconductor substrate, a fifth electrode provided on a first surface of the third semiconductor substrate, a sixth electrode provided on a second surface of the third semiconductor substrate, and a wiring, wiring including a third through electrode penetrating the third semiconductor substrate to connect the fifth electrode and the sixth electrode to each other; preparing a fourth semiconductor wafer, the fourth semiconductor wafer including a fourth semiconductor substrate, a seventh electrode provided on a first surface of the fourth semiconductor substrate, an eighth electrode provided on a second surface of the fourth semiconductor substrate, and a wiring, the wiring including a fourth through electrode penetrating the fourth semiconductor substrate to connect the seventh electrode and the eighth electrode to each other; stacking and integrating the first semiconductor wafer and the second semiconductor wafer and connecting the second electrode and the third electrode to each other to fabricate a first stacked wafer; stacking and integrating the third semiconductor wafer and the fourth semiconductor wafer and connecting the sixth electrode and the seventh electrode to each other to fabricate a second stacked wafer; and stacking and integrating the first stacked wafer and the second stacked wafer and connecting the fourth electrode and the fifth electrode to each other to fabricate a third stacked wafer.

In this method for manufacturing a semiconductor device, first, the first semiconductor wafer and the second semiconductor wafer are stacked to fabricate the first stacked wafer, and the third semiconductor wafer and the fourth semiconductor wafer are stacked to fabricate the second stacked wafer. Then, the first stacked wafer and the second stacked wafer are further stacked to fabricate the multilayer third stacked wafer. In this case, the number of stacked layers can be increased by doubling, so that a period for manufacturing a multilayer semiconductor device can be shortened as compared with a method of sequentially stacking layers one by one.

[2] In the method for manufacturing a semiconductor device according to [1], a first insulating layer may be provided on the first surface of the first semiconductor substrate, and a second insulating layer may be provided on the second surface of the first semiconductor substrate, and a third insulating layer may be provided on the first surface of the second semiconductor substrate, and a fourth insulating layer may be provided on the second surface of the second semiconductor substrate. In the fabricating the first stacked wafer, the second insulating layer and the third insulating layer may be bonded and integrated, and the second electrode and the third electrode may be bonded to each other, by applying at least one of heating or pressurization. In this case, a so-called hybrid bonding method can be used when the first semiconductor wafer and the second semiconductor wafer are stacked and integrated. It is therefore possible to bond fine electrodes to each other and reduce a height of the stacked body.

[3] In the method for manufacturing a semiconductor device according to [2], a fifth insulating layer may be provided on the first surface of the third semiconductor substrate, and a sixth insulating layer may be provided on the second surface of the third semiconductor substrate, and a seventh insulating layer may be provided on the first surface of the fourth semiconductor substrate, and an eighth insulating layer may be provided on the second surface of the fourth semiconductor substrate. In the fabricating the second stacked wafer, the sixth insulating layer and the seventh insulating layer may be bonded and integrated, and the sixth electrode and the seventh electrode may be bonded to each other, by applying at least one of heating or pressurization. In the fabricating the third stacked wafer, the fourth insulating layer and the fifth insulating layer may be bonded and integrated, and the fourth electrode and the fifth electrode may be bonded to each other, by applying at least one of heating or pressurization. In this case, a so-called hybrid bonding method can be used when the third semiconductor wafer and the fourth semiconductor wafer are stacked and integrated, and when the first stacked wafer and the second stacked wafer are stacked and integrated. It is therefore possible to bond fine electrodes to each other and reduce a height of the stacked body.

[4] In the method for manufacturing a semiconductor device according to [2] or [3], the first insulating layer, the second insulating layer, the third insulating layer, and the fourth insulating layer may contain at least one of an organic insulating material or an inorganic insulating material. In a case where each insulating layer contains an organic insulating material, even if unexpected fine particles or debris adheres to a bonding surface when hybrid bonding is performed, it can be expected that a bonding defect is reduced by being absorbed by the organic insulating material (see, for example, Non Patent Literature 5). In addition, in a case where each insulating layer contains an inorganic insulating material, it is easy to form a fine insulating layer and an electrode by using a back end of line (BEOL) wiring technology for connecting semiconductor transistors. Note that the fifth insulating layer, the sixth insulating layer, the seventh insulating layer, and the eighth insulating layer may similarly contain at least one of an organic insulating material or an inorganic insulating material.

[5] In the method for manufacturing a semiconductor device according to [4], the organic insulating material preferably contains bismaleimide, polyimide, a polyimide precursor, polyamideimide, benzocyclobutene (BCB), polybenzoxazole (PBO), or a PBO precursor. In this case, even if a heating temperature increases when the respective electrodes are bonded using the hybrid bonding method, it is possible to prevent bonding between the respective electrodes from being inhibited due to softening, or the like, of the insulating layers.

[6] In the method for manufacturing a semiconductor device according to [1], in the fabricating the first stacked wafer, the second electrode and the third electrode may be bonded to each other by a solder bump. In this case, the second electrode and the third electrode can be bonded more reliably. In the fabricating the second stacked wafer and the fabricating the third stacked wafer, the electrodes may be similarly bonded by solder bumps. Note that it is also possible to use solder bump bonding using a non conductive film (NCF).

[7] The method for manufacturing a semiconductor device according to any one of [1] to [6] may further include inspecting the first stacked wafer and the second stacked wafer before fabricating the third stacked wafer. In this case, a non-defective rate of the semiconductor device as a whole can be improved by causing a non-defective semiconductor wafer or a semiconductor wafer having a high non-defective rate to proceed to the next step except for a defective semiconductor wafer or a semiconductor wafer having a high defective rate.

[8] In the method for manufacturing a semiconductor device according to [7], the first stacked wafer may include a plurality of first semiconductor chip regions, the second stacked wafer may include a plurality of second semiconductor chip regions. In the inspecting, each of the plurality of first semiconductor chip regions may be inspected and each of the plurality of second semiconductor chip regions may be inspected. In the fabricating the third stacked wafer, a combination of each of the plurality of first semiconductor chip regions and each of the plurality of second semiconductor chip regions may be selected based on an inspection result in the inspecting. As a result, a non-defective rate of the semiconductor device as a whole can be further improved by causing a non-defective semiconductor wafer or a semiconductor wafer having a high non-defective rate to proceed to the next step except for a defective semiconductor wafer or a semiconductor wafer having a high defective rate.

[9] In the method for manufacturing a semiconductor device according to [8], in the fabricating the third stacked wafer, selection may be performed such that semiconductor chip regions determined to be non-defective in the inspecting overlap with each other. In this case, a non-defective rate of the semiconductor device can be further improved.

[10] The method for manufacturing a semiconductor device according to any one of [1] to [9] may further include fabricating a plurality of third stacked wafers by fabricating the third stacked wafer twice or more, and stacking the plurality of third stacked wafers to fabricate a fourth stacked wafer. In this case, a period for manufacturing a multilayer semiconductor device can be shortened as compared with a method of sequentially stacking layers one by one.

[11] The method for manufacturing a semiconductor device according to any one of [1] to [10] may further include singulating a stacked body including the third stacked wafer into chip-sized pieces to obtain at least one stacked semiconductor chip.

[12] The present disclosure relates to a semiconductor device as one aspect. This semiconductor device includes at least one stacked semiconductor chip manufactured by the method for manufacturing the semiconductor device according to [11], and a substrate on which the stacked semiconductor chip is mounted.

### Advantageous Effects of Invention

According to the present disclosure, it is possible to shorten a period for manufacturing a stacked body of semiconductor wafers.

### BRIEF DESCRIPTION OF DRAWINGS

FIG. 1 is a cross-sectional view illustrating an example of a cross-sectional configuration of a semiconductor device according to an embodiment of the present invention.

FIGS. 2A and 2B are cross-sectional views illustrating a method for manufacturing the semiconductor device illustrated in FIG. 1.

FIG. 3 is a cross-sectional view illustrating the method for manufacturing the semiconductor device illustrated in FIG. 1 and illustrates a step to be performed after the steps illustrated in FIGS. 2A and 2B.

FIG. 4 is a view for explaining a step of attaching wafers while reflecting a result in an inspection step.

FIG. 5 is a view for explaining a step of attaching wafers while reflecting a result in the inspection step.

FIG. 6 is a perspective view for explaining the step of attaching the wafers in FIGS. 4 and 5.

### DESCRIPTION OF EMBODIMENT

Hereinafter, an embodiment according to the present invention will be described in detail with reference to the drawings. In the following description, the same or corresponding portions are denoted by the same reference numerals, and redundant description is omitted. Unless otherwise specified, a positional relationship such as up, down, left, and right is based on a positional relationship illustrated in the drawings. Dimensional ratios in the drawings are not limited to the illustrated ratios.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as intended action of the step is achieved.

In the present specification, a numerical range indicated using “from . . . to . . . ” indicates a range from a numerical value described after “from” to a numerical value described after “to” as a minimum value and a maximum value, respectively. In numerical ranges described in stages in the present specification, an upper limit value or a lower limit value of a numerical range in a certain stage may be replaced with an upper limit value or a lower limit value of a numerical range in another stage. In the numerical range described in the present specification, an upper limit value or a lower limit value of the numerical range may be replaced with a value indicated in Examples.

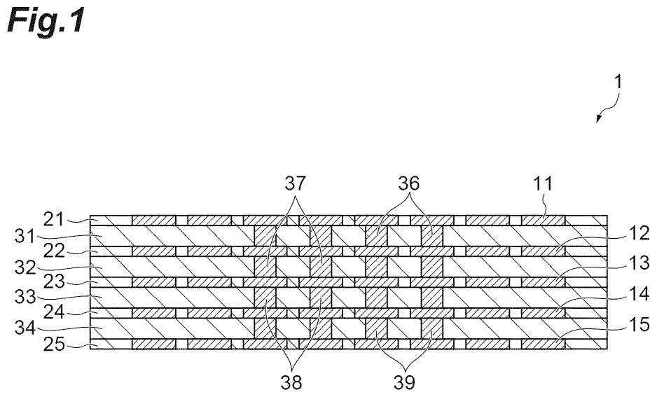

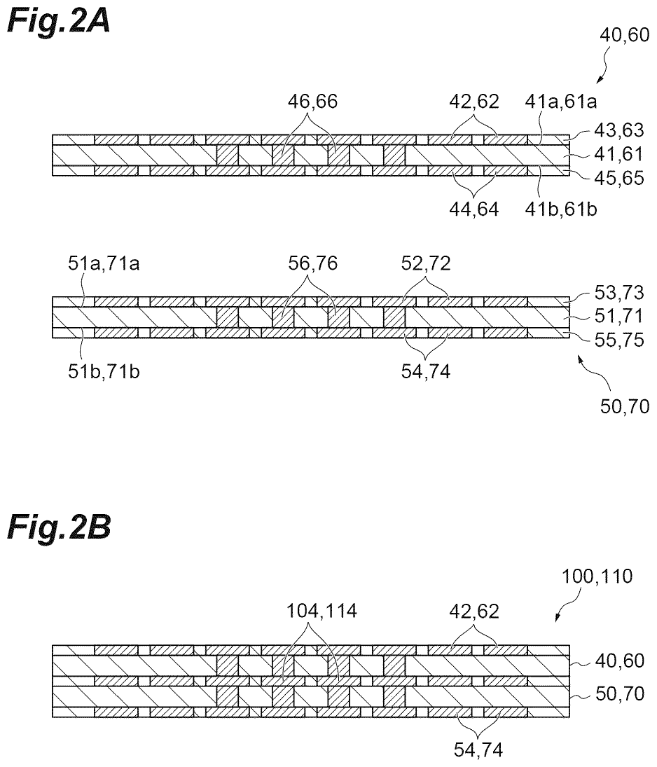

FIG. 1 is a view illustrating an example of a semiconductor device manufactured by a manufacturing method according to an embodiment of the present invention. As illustrated in FIG. 1, a semiconductor device 1 (corresponding to a third stacked wafer 120) is a three-dimensional stacked body in which four semiconductor wafers are stacked. The semiconductor device 1 includes five wiring electrodes 11 to 15, five insulating layers 21 to 25, and semiconductor substrates 31 to 34. The wiring electrodes 11 are formed in the insulating layer 21, and the wiring electrodes 12 are formed in the insulating layer 22. The wiring electrodes 13 are formed in the insulating layer 23. The wiring electrodes 14 are formed in the insulating layer 24. The wiring electrode 15 are formed in the insulating layer 25. The respective semiconductor substrates 31 to 34 are, for example, silicon wafers and correspond to semiconductor substrates 41, 51, 61, and 71 to be described later (see FIGS. 2A and 2B). While in the semiconductor device 1 illustrated in FIG. 1, for example, an example in which four layers of semiconductor wafers are stacked is illustrated, the present invention is not limited thereto, and a stacked body in which multiple layers of semiconductor wafers (for example, eight layers of semiconductor wafers or 16 layers of semiconductor wafers) are further stacked may be used.

The semiconductor device 1 is further provided with through electrodes 36 to 39 that penetrate the respective semiconductor wafers. Each through electrodes 36 penetrates the semiconductor substrate 31 to connect the wiring electrode 11 and the wiring electrode 12. Each through electrode 37 penetrates the semiconductor substrate 32 to connect the wiring electrode 12 and the wiring electrode 13. Each through electrode 38 penetrates the semiconductor substrate 33 to connect the wiring electrode 13 and the wiring electrode 14. Each through electrode 39 penetrates the semiconductor substrate 34 to connect the wiring electrode 14 and the wiring electrode 15. The respective through electrodes 36 to 39 are, for example, through silicon vias (TSVs). In addition, each of the through electrodes 36 to 39 may be configured to directly connect the corresponding wiring electrodes or may be configured to connect the corresponding wiring electrodes as a wiring including two or more through electrodes and an electrode connecting the two or more through electrodes.

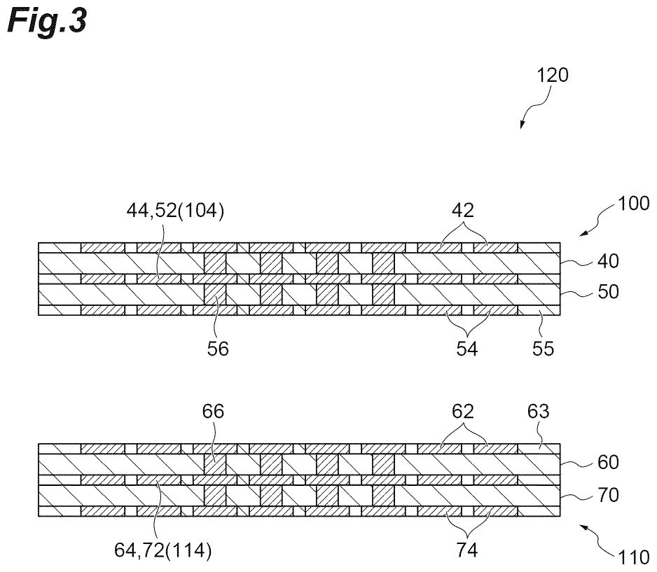

Next, a method for manufacturing the semiconductor device 1 will be described with reference to FIGS. 2A and 2B and FIG. 3. FIGS. 2A and 2B are cross-sectional views illustrating the method for manufacturing the semiconductor device illustrated in FIG. 1. FIG. 3 is a cross-sectional view illustrating the method for manufacturing the semiconductor device illustrated in FIG. 1 and illustrates a step to be performed after the steps illustrated in FIGS. 2A and 2B. This manufacturing method includes the following steps [A] to [G].
Step A: a step of preparing a first semiconductor wafer, the first semiconductor wafer including a first semiconductor substrate, a first electrode provided on a first surface of the first semiconductor substrate, a second electrode provided on a second surface of the first semiconductor substrate, and a wiring, this wiring including a first through electrode penetrating the first semiconductor substrate to connect the first electrode and the second electrode to each other.
Step B: a step of preparing a second semiconductor wafer, the second semiconductor wafer including a second semiconductor substrate, a third electrode provided on a first surface of the second semiconductor substrate, a fourth electrode provided on a second surface of the second semiconductor substrate, and a wiring, this wiring including a second through electrode penetrating the second semiconductor substrate to connect the third electrode and the fourth electrode to each other.
Step C: a step of preparing a third semiconductor wafer, the third semiconductor wafer including a third semiconductor substrate, a fifth electrode provided on a first surface of the third semiconductor substrate, a sixth electrode provided on a second surface of the third semiconductor substrate, and a wiring, this wiring including a third through electrode penetrating the third semiconductor substrate to connect the fifth electrode and the sixth electrode to each other.
Step D: a step of preparing a fourth semiconductor wafer, the fourth semiconductor wafer including a fourth semiconductor substrate, a seventh electrode provided on a first surface of the fourth semiconductor substrate, an eighth electrode provided on a second surface of the fourth semiconductor substrate, and a wiring, this wiring including a fourth through electrode penetrating the fourth semiconductor substrate to connect the seventh electrode and the eighth electrode to each other.
Step E: a step of stacking and integrating the first semiconductor wafer and the second semiconductor wafer and connecting the second electrode and the third electrode to each other to fabricate a first stacked wafer.
Step F: a step of stacking and integrating the third semiconductor wafer and the fourth semiconductor wafer and connecting the sixth electrode and the seventh electrode to each other to fabricate a second stacked wafer.
Step G: a step of stacking and integrating the first stacked wafer and the second stacked wafer and connecting the fourth electrode and the fifth electrode to each other to manufacture a third stacked wafer.

### [Step A]

In step A, as illustrated in FIG. 2A, a first semiconductor wafer 40 is prepared. The first semiconductor wafer 40 includes a semiconductor substrate 41 (first semiconductor substrate), a plurality of electrodes 42 (first electrode) provided on a first surface 41a of the semiconductor substrate 41, an insulating layer 43 (first insulating layer) provided on the first surface 41a of the semiconductor substrate 41, a plurality of electrodes 44 (second electrode) provided on a second surface 41b of the semiconductor substrate 41, an insulating layer 45 (second insulating layer) provided on the second surface 41b of the semiconductor substrate 41, and a wiring including through electrodes 46 (first through electrode) penetrating the semiconductor substrate 41 to connect the electrodes 42 and 44 to each other.

In step A, first, the semiconductor substrate 41, which is a silicon substrate on which an integrated circuit including semiconductor elements and a wiring connecting the semiconductor elements is formed, is prepared. A thickness of the semiconductor substrate 41 is, for example, 4 μm to 775 μm. When the semiconductor substrate 41 is prepared, next, holes each penetrating the semiconductor substrate 41 are provided by a predetermined method, and a plurality of through electrodes 46 filling the holes are formed. The through electrode 46 is a so-called TSV, and a known method such as a Bosch process (Non Patent Literature 6) can be used as a method for forming the through electrodes.

Subsequently, in step A, the plurality of electrodes 42 to be wiring electrodes 11 and the insulating layer 43 to be the insulating layer 21 are formed on the first surface 41a of the semiconductor substrate 41 formed of silicon, or the like. Each electrode 42 can be formed by a method of providing a resist opening and depositing a conductive material such as copper in the opening by electroplating. The insulating layer 43 is formed of, for example, an organic insulating material. For example, the insulating layer 43 can be formed by applying liquid polyimide (PI) onto the first surface 41a of the semiconductor substrate 41 on which the electrodes 42 are formed by spin coating and curing the polyimide. The electrodes 42 and the insulating layer 43 may be formed by other methods. Thicknesses of the electrodes 42 and the insulating layer 43 are, for example, from 1 μm to 10 μm.

As the organic insulating material to be used as the insulating layer 43, for example, a polyimide precursor (for example, a polyimide amic ester or a polyamic acid), a polyamideimide, a bismaleimide, benzocyclobutene (BCB), polybenzoxazole (PBO), a PBO precursor, or the like, can be used other than polyimide. These organic insulating materials containing polyimide are soft materials having a lower elastic modulus than inorganic materials such as silicon oxide (SiO₂). By using such an organic material, when the organic insulating layers are bonded to each other in steps E to G described later, even if fine debris exists on the insulating layer, the debris is absorbed into the organic insulating layer, which prevents a bonding failure due to the debris, so that the organic insulating layers can be reliably bonded to each other. Note that the insulating layer 43 may be formed of an inorganic material such as silicon oxide.

Further, in step A, the plurality of electrodes 44 to be part of the wiring electrode 12 and the insulating layer 45 to be part of the insulating layer 22 are formed on the second surface 41b of the semiconductor substrate 41 formed of silicon, or the like. As a method of forming the electrodes 44 and the insulating layer 45, the same method as the method of forming the electrodes 42 and the insulating layer 43 described above can be used, and thus, the description thereof will be omitted. As described above, the first semiconductor wafer 40 is formed. Note that while in the first semiconductor wafer 40, the electrode 42 and the electrode 44 are directly connected by the through electrode 46 in the example illustrated in FIGS. 2A and 2B, the electrode 42 and the electrode 44 may be connected by a wiring including a plurality of through electrodes and electrodes connecting the through electrodes. The same may be applied to the following other semiconductor wafers.

### [Step B]

In step B, a second semiconductor wafer 50 is prepared. The second semiconductor wafer 50 includes a semiconductor substrate 51 (second semiconductor substrate), a plurality of electrodes 52 (third electrode) provided on a first surface 51a of the semiconductor substrate 51, an insulating layer 53 (third insulating layer) provided on the first surface 51a of the semiconductor substrate 51, a plurality of electrodes 54 (fourth electrode) provided on a second surface 51b of the semiconductor substrate 51, an insulating layer 55 (fourth insulating layer) provided on the second surface 51b of the semiconductor substrate 51, and a wiring including a plurality of through electrodes 56 (second through electrode) penetrating the semiconductor substrate 51 to connect the electrodes 52 and 54 to each other. In step B, the materials and the method of forming the electrodes 52 and 54, the insulating layers 53 and 55, and the through electrodes 56 in the second semiconductor wafer 50 are similar to those in the first semiconductor wafer 40, and thus, detailed description thereof will be omitted. Note that the respective electrodes 52 in the second semiconductor wafer 50 constitute part of the wiring electrodes 12 of the semiconductor device 1 illustrated in FIG. 1, and the insulating layer 53 constitutes part of the insulating layer 22. The electrodes 54 in the second semiconductor wafer 50 constitute part of the wiring electrodes 13 of the semiconductor device 1 illustrated in FIG. 1, and the insulating layer 55 constitutes part of the insulating layer 23.

### [Step C]

In step C, a third semiconductor wafer 60 is prepared. The third semiconductor wafer 60 includes a semiconductor substrate 61 (third semiconductor substrate), a plurality of electrodes 62 (fifth electrode) provided on a first surface 61a of the semiconductor substrate 61, an insulating layer 63 (fifth insulating layer) provided on the first surface 61a of the semiconductor substrate 61, a plurality of electrodes 64 (sixth electrode) provided on a second surface 61b of the semiconductor substrate 61, an insulating layer 65 (sixth insulating layer) provided on the second surface 61b of the semiconductor substrate 61, and a wiring including a plurality of through electrodes 66 (third through electrode) penetrating the semiconductor substrate 61 to connect the electrodes 62 and 64 to each other. In step C, the materials and the method of forming the electrodes 62 and 64, the insulating layers 63 and 65, and the through electrodes 66 in the third semiconductor wafer 60 are similar to those in the first semiconductor wafer 40, and the like, and thus, detailed description thereof will be omitted. Note that the electrodes 62 in the third semiconductor wafer 60 constitute part of the wiring electrodes 13 of the semiconductor device 1 illustrated in FIG. 1, and the insulating layer 63 constitutes part of the insulating layer 23. The electrodes 64 in the third semiconductor wafer 60 constitute part of the wiring electrodes 14 of the semiconductor device 1 illustrated in FIG. 1, and the insulating layer 65 constitutes part of the insulating layer 24.

### [Step D]

In step D, a fourth semiconductor wafer 70 is prepared. The fourth semiconductor wafer 70 includes a semiconductor substrate 71 (fourth semiconductor substrate), a plurality of electrodes 72 (seventh electrode) provided on a first surface 71a of the semiconductor substrate 71, an insulating layer 73 (seventh insulating layer) provided on the first surface 71a of the semiconductor substrate 71, a plurality of electrodes 74 (eighth electrode) provided on a second surface 71b of the semiconductor substrate 71, an insulating layer 75 (eighth insulating layer) provided on the second surface 71b of the semiconductor substrate 71, and a wiring including a plurality of through electrodes 76 (fourth through electrode) penetrating the semiconductor substrate 71 to connect the electrodes 72 and 74 to each other. In step D, the materials and the method of forming the electrodes 72 and 74, the insulating layers 73 and 75, and the through electrodes 76 in the fourth semiconductor wafer 70 are similar to those in the first semiconductor wafer 40 and the like, and thus, detailed description thereof will be omitted. The electrodes 72 in the fourth semiconductor wafer 70 constitutes part of the wiring electrodes 14 of the semiconductor device 1 illustrated in FIG. 1, and the insulating layer 73 constitutes part of the insulating layer 24. The electrodes 74 in the fourth semiconductor wafer 70 constitute the wiring electrodes 15 of the semiconductor device 1 illustrated in FIG. 1, and the insulating layer 75 constitutes the insulating layer 25.

### [Step E]

In step E, as illustrated in FIGS. 2A and 2B, when preparation of the first semiconductor wafer 40 and the second semiconductor wafer 50 is completed, the first semiconductor wafer 40 and the second semiconductor wafer 50 are stacked and integrated, and the electrodes 44 and the electrodes 52 are connected to each other to fabricate a first stacked wafer 100. In other words, the first semiconductor wafer 40 and the second semiconductor wafer 50 are integrated by hybrid bonding by applying heating and pressurization to the both. A heating temperature for the first semiconductor wafer 40 and the second semiconductor wafer 50 is, for example, 150° C. to 400° C., and the pressure is 0.04 MPa to 10 MPa. By such bonding, the insulating layer 45 of the first semiconductor wafer 40 and the insulating layer 53 of the second semiconductor wafer 50 are firmly bonded (connected) to each other, and each electrode 44 of the first semiconductor wafer 40 and each electrode 52 of the second semiconductor wafer are firmly bonded (connected) to each other. The electrode 44 and the electrode 52 are bonded to form the electrode 104 illustrated in FIG. 2B. The electrode 104 is connected to both the through electrodes 46 and 56, and the electrode 42 and the electrode 54 are electrically connected to each other. The electrodes 104 correspond to the wiring electrodes 12 illustrated in FIG. 1.

### [Step F]

In step F, as illustrated in FIGS. 2A and 2B, when preparation of the third semiconductor wafer 60 and the fourth semiconductor wafer 70 is completed, the third semiconductor wafer 60 and the fourth semiconductor wafer 70 are stacked and integrated, and the electrodes 64 and the electrodes 72 are connected to each other to fabricate a second stacked wafer 110. In other words, the third semiconductor wafer 60 and the fourth semiconductor wafer 70 are integrated by hybrid bonding by applying heating and pressurization to the both. A heating temperature for the third semiconductor wafer 60 and the fourth semiconductor wafer 70 is, for example, 150° C. to 400° C., and the pressure is 0.04 MPa to 10 MPa. By such bonding, the insulating layer 65 of the third semiconductor wafer 60 and the insulating layer 73 of the fourth semiconductor wafer 70 are firmly bonded (connected) to each other, and each electrode 64 of the third semiconductor wafer 60 and each electrode 72 of the fourth semiconductor wafer 70 are firmly bonded (connected) to each other. The electrode 64 and the electrode 72 are bonded to form the electrode 114 illustrated in FIG. 2B. The electrode 114 is connected to both the through electrodes 66 and 76, and the electrode 62 and the electrode 74 are electrically connected to each other. The electrodes 114 corresponds to the wiring electrodes 14 illustrated in FIG. 1.

### [Step G]

In step G, as illustrated in FIG. 3, when preparation of the first stacked wafer 100 and the second stacked wafer 110 is completed, the first stacked wafer 100 and the second stacked wafer 110 are stacked and integrated, and the electrodes 54 and the electrodes 62 are respectively connected to each other to fabricate a third stacked wafer 120. In other words, the first stacked wafer 100 and the second stacked wafer 110 are integrated by hybrid bonding by applying heating and pressurization to the both. A heating temperature for the first stacked wafer 100 and the second stacked wafer 110 is, for example, 150° C. to 400° C., and the pressure is 0.04 MPa to 10 MPa. By such bonding, the insulating layer 55 of the first stacked wafer 100 and the insulating layer 63 of the second stacked wafer 110 are firmly bonded (connected) to each other, and each electrode 54 of the first stacked wafer 100 and each electrode 62 of the second stacked wafer 110 are firmly bonded (connected) to each other. The electrode 54 and the electrode 62 are bonded to form the wiring electrode 13 illustrated in FIG. 1. The wiring electrode 13 is connected to both of the through electrodes 56 and 66, and the electrodes 42, 44, 52, 54, 62, 64, 72, and 74 are electrically connected to each other.

As described above, the semiconductor device 1 which is a stacked body in which four layers of semiconductor wafers are stacked is formed (see also FIG. 1). After the semiconductor device 1 is formed, the semiconductor device 1 may be singulated into chip-sized pieces by dicing, or the like, to obtain a large number of stacked semiconductor chips (at least one stacked semiconductor chip). In this case, the singulated stacked semiconductor chip can be mounted on another semiconductor substrate, or the like, to form a semiconductor device.

As described above, in the method for manufacturing the semiconductor device according to the present embodiment, first, the first semiconductor wafer 40 and the second semiconductor wafer 50 are stacked to fabricate the first stacked wafer 100, and the third semiconductor wafer 60 and the fourth semiconductor wafer 70 are stacked to fabricate the second stacked wafer 110. Then, the first stacked wafer 100 and the second stacked wafer 110 are stacked to fabricate the multilayer third stacked wafer 120. According to this manufacturing method, the number of stacked layers can be increased by doubling, so that a period for manufacturing a multilayer semiconductor device can be shortened as compared with a method of sequentially stacking layers one by one.

In the method for manufacturing the semiconductor device according to the present embodiment, the insulating layer 43 is provided on the first surface 41a of the semiconductor substrate 41, the insulating layer 45 is provided on the second surface 41b of the semiconductor substrate 41, the insulating layer 53 is provided on the first surface 51a of the semiconductor substrate 51, and the insulating layer 55 is provided on the second surface 51b of the semiconductor substrate 51. Then, in this manufacturing method, in the step of fabricating the first stacked wafer 100, the insulating layer 45 and the insulating layer 53 are bonded to each other and integrated, and the electrodes 44 and the electrodes 52 are bonded to each other by applying heating and pressurization. As a result, a so-called hybrid bonding method can be used when the first semiconductor wafer 40 and the second semiconductor wafer 50 are stacked and integrated. It is therefore possible to bond fine electrodes to each other and reduce a height of the stacked body.

In the method for manufacturing the semiconductor device according to the present embodiment, further, the insulating layer 63 is provided on the first surface 61a of the semiconductor substrate 61, the insulating layer 65 is provided on the second surface 61b of the semiconductor substrate 61, the insulating layer 73 is provided on the first surface 71a of the semiconductor substrate 71, and the insulating layer 75 is provided on the second surface 71b of the semiconductor substrate 71.

Then, in the step of fabricating the second stacked wafer 110, the insulating layer 65 and the insulating layer 73 are stacked and integrated, and the electrodes 64 and the electrode s72 are bonded to each other by applying heating and pressurization. In the step of fabricating the third stacked wafer 120, the insulating layer 55 and the insulating layer 63 are bonded to each other and integrated, and the electrodes 54 and the electrodes 62 are bonded to each other by applying heating and pressurization. As a result, a so-called hybrid bonding method can be used when the third semiconductor wafer 60 and the fourth semiconductor wafer 70 are stacked and integrated, and when the first stacked wafer 100 and the second stacked wafer 110 are stacked and integrated. It is therefore possible to bond fine electrodes to each other and reduce a height of the stacked body.

In the method for manufacturing the semiconductor device according to the present embodiment, each of the insulating layers 43, 45, 53, 55, 63, 65, 73, and 75 contains an organic insulating material. As a result, even if debris adheres to a bonding surface when hybrid bonding is performed, the debris is absorbed by the organic insulating material, so that a bonding failure can be reduced. When each of the insulating layers 43, 45, 53, 55, 63, 65, 73, and 75 contains an inorganic insulating material, a fine insulating layer and a fine electrode are easily formed.

In the method for manufacturing the semiconductor device according to the present embodiment, the organic insulating material constituting each of the insulating layers 43, 45, 53, 55, 63, 65, 73, and 75 preferably contains bismaleimide, polyimide, a polyimide precursor, polyamideimide, benzocyclobutene (BCB), polybenzoxazole (PBO), or a PBO precursor. In this case, even if a heating temperature increases when the respective electrodes are bonded using the hybrid bonding method, it is possible to prevent bonding between the respective electrodes from being inhibited due to softening, or the like, of the insulating layers.

Note that two or more third stacked wafers 120 (see FIG. 3) in which the first stacked wafer 100 and the second stacked wafer 110 are bonded may be fabricated, and the two third stacked wafers 120 may be further stacked using hybrid bonding like bonding of the first stacked wafer 100 and the second stacked wafer 110 to form a fourth stacked wafer. In this case, it is possible to obtain a semiconductor device (fourth stacked wafer) in which eight layers of semiconductor wafers are stacked, and to efficiently manufacture the semiconductor device.

Although the embodiment of the present disclosure has been described above, the present invention is not limited to the above-described embodiment, and modifications may be appropriately made without departing from the gist thereof. For example, in the above-described embodiment, an example in which the semiconductor wafers and the stacked semiconductor wafers are stacked and bonded by hybrid bonding has been described, but the present invention is not limited thereto. For example, in the step of fabricating the first stacked wafer 100, the electrode 44 and the electrode 52 may be bonded by a solder bump. By this method, the electrode 44 and the electrode 52 can be reliably bonded. In this case, solder bump bonding using a non-conductive film (NCF) may be used, or an underfill may be injected and fixed between wafers where electrodes are bonded to each other. In addition, in the step of fabricating the second stacked wafer 110 and the step of fabricating the third stacked wafer 120, the electrodes may be similarly bonded by solder bumps.

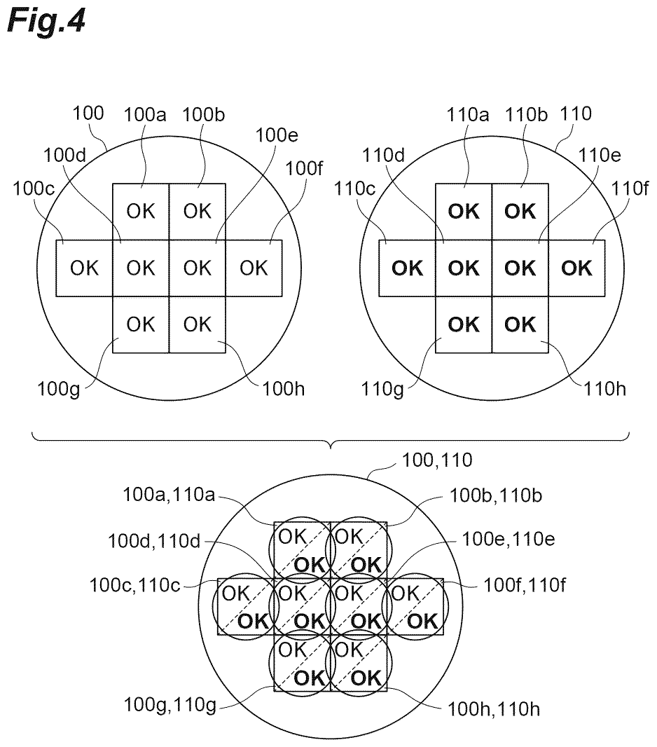

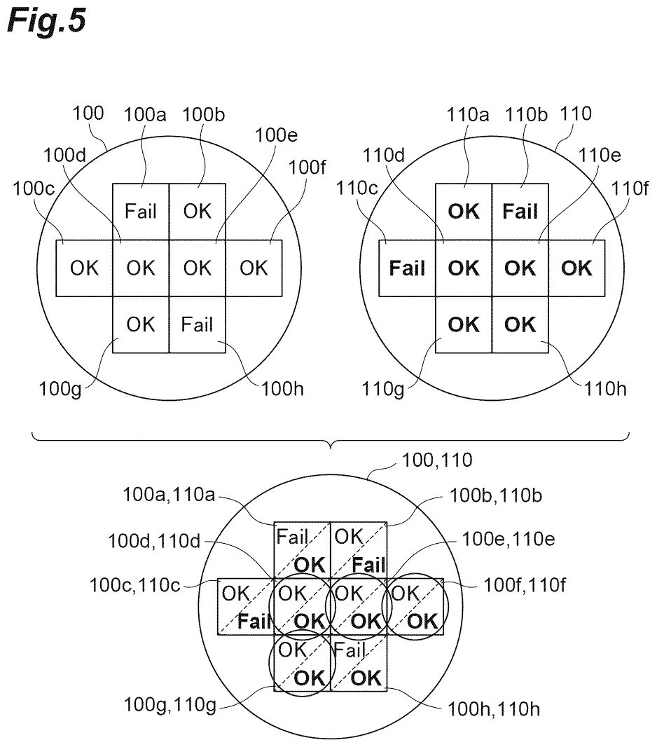

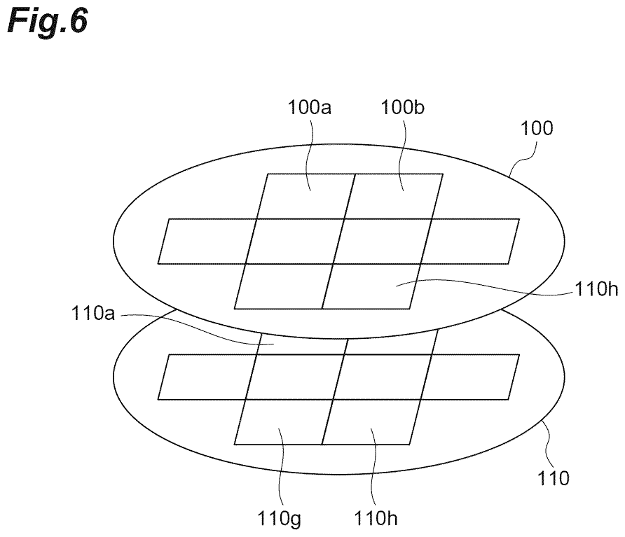

In the above-described method for manufacturing the semiconductor device, stacked semiconductor wafers are attached as a unit. Thus, in the method for manufacturing the semiconductor device according to the present embodiment, before the wafer stacked body is fabricated (for example, before the first stacked wafer 100 and the second stacked wafer 110 are stacked as illustrated in FIG. 6), as illustrated in FIG. 4, conduction inspection may be performed on semiconductor chip regions 100a to 100h (a plurality of first semiconductor chip regions) and semiconductor chip regions 110a to 110h (a plurality of second semiconductor chip regions) included in each stacked wafer. In this case, each stacked wafer is a large-sized wafer including a plurality of semiconductor chip regions (regions to be semiconductor chips when each stacked wafer is singulated), and the conduction inspection is performed by inspecting conduction and insulation of each semiconductor chip region with a flying probe, or the like, from both surfaces of the stacked wafer. In a case where there is a semiconductor chip region determined to be defective (Fail) as a result of the conduction inspection (see FIG. 5), a non-defective rate (yield) as a whole can be improved by not manufacturing the portion or not using the substrate. FIG. 4 illustrates a case where all the semiconductor chip regions are non-defective (OK), and FIG. 5 illustrates a case where some wiring portions are defective (Fail). In the example of FIG. 5, for example, selection is performed so that the semiconductor chip regions determined to be non-defective (OK) overlap with each other, and for example, the semiconductor chip regions 100d and 110d, the semiconductor chip regions 100e and 110e, the semiconductor chip regions 100f and 110f, and the semiconductor chip regions 100 g and 110 g can be used as subsequent products, and the other semiconductor chip regions can be prevented from being used for subsequent manufacturing.

In addition, a plurality of first stacked wafers 100 and a plurality of second stacked wafers 110 may be prepared, and a combination of the first stacked wafer 100 and the second stacked wafer 110 may be selected so that the number of combinations including semiconductor chip regions determined to be non-defective products as a whole increases. For example, in FIG. 5, one first stacked wafer 100 and one second stacked wafer 110 are simply combined, and thus, there are only four semiconductor chip regions that become non-defective by the combinations. However, by preparing a large number of stacked wafers, a rate of obtaining combinations of non-defective products can be increased, and the non-defective rate of the combinations as a whole can be improved. In such selection processing, selection may be performed by calculating a non-defective rate (yield) when all the semiconductor wafers and the stacked semiconductor wafers are combined using a computer, or other processing methods may be used. As described above, the non-defective rate of the semiconductor device as a whole can be improved by causing a non-defective semiconductor wafer or a semiconductor wafer having a high non-defective rate to proceed to the next step except for a defective semiconductor wafer or a semiconductor wafer having a high defective rate.

In addition, also in a case where the third stacked wafers 120 fabricated by being inspected in this manner are further stacked, similarly, conduction inspection may be performed in advance, and selection and stacking may be performed so as to obtain a more optimal combination based on the inspection result. In the inspection step and the selection step of non-defective products described above, a case has been described as an example where the first stacked wafer 100 and the second stacked wafer 110 are bonded to each other. However, the present invention is not limited thereto, and may be applied to a case where the first semiconductor wafer 40 and the second semiconductor wafer 50 are bonded to each other or a case where the third semiconductor wafer 60 and the fourth semiconductor wafer 70 are bonded to each other. By performing such inspection and selection steps, a non-defective rate can be reliably improved.

### REFERENCE SIGNS LIST

1 Semiconductor device (third stacked wafer)
40 First semiconductor wafer
41 Semiconductor substrate (first semiconductor substrate)
41a First surface
41b Second surface
42 Electrode (first electrode)
43 Insulating layer (first insulating layer)
44 Electrode (second electrode)
45 Insulating layer (second insulating layer)
46 Through electrode (first through electrode)
50 Second semiconductor wafer
51 Semiconductor substrate (second semiconductor substrate)
51a First surface
51b Second surface
52 Electrode (third electrode)
53 Insulating layer (third insulating layer)
54 Electrode (fourth electrode)
55 Insulating layer (fourth insulating layer)
56 Through electrode (second through electrode)
60 Third semiconductor wafer
61 Semiconductor substrate (third semiconductor substrate)
61a First surface
61b Second surface
62 Electrode (fifth electrode)
63 Insulating layer (fifth insulating layer)
64 Electrode (sixth electrode)
65 Insulating layer (sixth insulating layer)
66 Through electrode (third through electrode)
70 Fourth semiconductor wafer
71 Semiconductor substrate (fourth semiconductor substrate)
71a First surface
71b Second surface
72 Electrode (seventh electrode)
73 Insulating layer (seventh insulating layer)
74 Electrode (eighth electrode)
75 Insulating layer (eighth insulating layer)
76 Through electrode (fourth through electrode)
100 First stacked wafer
110 Second stacked wafer
120 Third stacked wafer

1. A method for manufacturing a semiconductor device, the method comprising:
preparing a first semiconductor wafer, the first semiconductor wafer including a first semiconductor substrate, a first electrode provided on a first surface of the first semiconductor substrate, a second electrode provided on a second surface of the first semiconductor substrate, and a first wiring, the first wiring including a first through electrode penetrating the first semiconductor substrate to connect the first electrode and the second electrode to each other;
preparing a second semiconductor wafer, the second semiconductor wafer including a second semiconductor substrate, a third electrode provided on a first surface of the second semiconductor substrate, a fourth electrode provided on a second surface of the second semiconductor substrate, and a second wiring, the second wiring including a second through electrode penetrating the second semiconductor substrate to connect the third electrode and the fourth electrode to each other;
preparing a third semiconductor wafer, the third semiconductor wafer including a third semiconductor substrate, a fifth electrode provided on a first surface of the third semiconductor substrate, a sixth electrode provided on a second surface of the third semiconductor substrate, and a third wiring, the third wiring including a third through electrode penetrating the third semiconductor substrate to connect the fifth electrode and the sixth electrode to each other;
preparing a fourth semiconductor wafer, the fourth semiconductor wafer including a fourth semiconductor substrate, a seventh electrode provided on a first surface of the fourth semiconductor substrate, an eighth electrode provided on a second surface of the fourth semiconductor substrate, and a fourth wiring, the fourth wiring including a fourth through electrode penetrating the fourth semiconductor substrate to connect the seventh electrode and the eighth electrode to each other;
stacking and integrating the first semiconductor wafer and the second semiconductor wafer and connecting the second electrode and the third electrode to each other to fabricate a first stacked wafer;
stacking and integrating the third semiconductor wafer and the fourth semiconductor wafer and connecting the sixth electrode and the seventh electrode to each other to fabricate a second stacked wafer; and
stacking and integrating the first stacked wafer and the second stacked wafer and connecting the fourth electrode and the fifth electrode to each other to fabricate a third stacked wafer.

2. The method for manufacturing a semiconductor device according to claim 1,
wherein a first insulating layer is provided on the first surface of the first semiconductor substrate, and a second insulating layer is provided on the second surface of the first semiconductor substrate,
wherein, a third insulating layer is provided on the first surface of the second semiconductor substrate, and a fourth insulating layer is provided on the second surface of the second semiconductor substrate, and
wherein, in the fabricating the first stacked wafer, the second insulating layer and the third insulating layer are bonded to be integrated, and the second electrode and the third electrode are bonded to each other, by applying at least one of heating or pressurization.

3. The method for manufacturing a semiconductor device according to claim 2,
wherein a fifth insulating layer is provided on the first surface of the third semiconductor substrate, and a sixth insulating layer is provided on the second surface of the third semiconductor substrate,
wherein a seventh insulating layer is provided on the first surface of the fourth semiconductor substrate, and an eighth insulating layer is provided on the second surface of the fourth semiconductor substrate,
wherein, in the fabricating the second stacked wafer, the sixth insulating layer and the seventh insulating layer are bonded to be integrated, and the sixth electrode and the seventh electrode are bonded to each other, by applying at least one of heating or pressurization, and
wherein, in the fabricating the third stacked wafer, the fourth insulating layer and the fifth insulating layer are bonded to be integrated, and the fourth electrode and the fifth electrode are bonded to each other, by applying at least one of heating or pressurization.

4. The method for manufacturing a semiconductor device according to claim 2,
wherein, the first insulating layer, the second insulating layer, the third insulating layer, and the fourth insulating layer contain at least one of an organic insulating material or an inorganic insulating material.

5. The method for manufacturing a semiconductor device according to claim 4,
wherein the organic insulating material contains bismaleimide, polyimide, a polyimide precursor, polyamideimide, benzocyclobutene (BCB), polybenzoxazole (PBO), or a PBO precursor.

6. The method for manufacturing a semiconductor device according to claim 1,
wherein, in the fabricating the first stacked wafer, the second electrode and the third electrode are bonded to each other by a solder bump.

7. The method for manufacturing a semiconductor device according to claim 1, further comprising:
inspecting the first stacked wafer and the second stacked wafer before fabricating the third stacked wafer.

8. The method for manufacturing a semiconductor device according to claim 7,
wherein the first stacked wafer includes a plurality of first semiconductor chip regions, and the second stacked wafer includes a plurality of second semiconductor chip regions,
wherein, in the inspecting, each of the plurality of first semiconductor chip regions is inspected and each of the plurality of second semiconductor chip regions is inspected, and
wherein, in the fabricating the third stacked wafer, a combination of each of the plurality of first semiconductor chip regions and each of the plurality of second semiconductor chip regions is selected based on an inspection result in the inspecting.

9. The method for manufacturing a semiconductor device according to claim 8,
wherein, in the fabricating the third stacked wafer, selection is performed such that semiconductor chip regions determined to be non-defective in the inspecting overlap with each other.

10. The method for manufacturing a semiconductor device according to claim 1, further comprising:
fabricating a plurality of third stacked wafers by performing the fabricating the third stacked wafer twice or more; and
stacking the plurality of third stacked wafers to fabricate a fourth stacked wafer.

11. The method for manufacturing a semiconductor device according to claim 1, further comprising:
singulating a stacked body including the third stacked wafer into chip-sized pieces to obtain at least one stacked semiconductor chip.

12. A semiconductor device comprising:
at least one stacked semiconductor chip manufactured by the method for manufacturing the semiconductor device according to claim 11; and
a substrate on which the stacked semiconductor chip is mounted.
